(19) United States
(12) Patent Application Publication
(10) Pub. No.: US 2026/0052845 A1
(43) Pub. Date: Feb. 19, 2026

(54) DISPLAY DEVICE, ELECTRONIC DEVICE INCLUDING THE SAME, AND METHOD FOR FABRICATION THEREOF

(71) Applicant: Samsung Display Co., LTD., Yongin-si (KR)

(72) Inventors: Hyun Eok SHIN, Yongin-si (KR); Joon Yong PARK, Yongin-si (KR); Su Kyoung YANG, Yongin-si (KR); Dong Min LEE, Yongin-si (KR)

(21) Appl. No.: 19/064,311

(22) Filed: Feb. 26, 2025

(30) Foreign Application Priority Data
Aug. 19, 2024 (KR) 10-2024-0110199

(51) Int. Cl. H10K 59/122; H10K 59/12; H10K 59/121

(52) U.S. Cl. CPC H10K 59/122; H10K 59/1201; H10K 59/1213

(57) ABSTRACT

A display device includes: a pixel circuit comprising a transistor on a substrate; an anode electrode on an emission area of the substrate; a pixel defining layer on a non-emission area of the substrate and defining a first opening; a bank structure on the pixel defining layer and defining a second opening, the bank structure comprising a first bank layer and a second bank layer; a first cathode electrode on the anode electrode, contacting the bank structure, and electrically connected to the transistor; and a second cathode electrode spaced apart from the first cathode electrode with the pixel defining layer and the bank structure therebetween, wherein the second cathode electrode contacts the bank structure, and the bank structure contacting the first cathode electrode and the bank structure contacting the second cathode electrode are spaced apart from each other with a third opening therebetween, in a portion overlapping the non-emission area.

### CROSS-REFERENCE TO RELATED APPLICATION

The present application claims priority to and the benefit of Korean Patent Application No. 10-2024-0110199, filed on Aug. 19, 2024, in the Korean Intellectual Property Office, the entire disclosure of which is incorporated herein by reference.

### BACKGROUND

### 1. Field

Aspects of some embodiments of the present disclosure relate to a display device, an electronic device including the same, and a method for fabrication thereof.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions. The display device may be a flat panel display device such as a liquid crystal display device, a field emission display device and an organic light emitting display device. Among the flat panel display devices, in the light emitting display device, because each of pixels of a display panel includes a light emitting element capable of emitting light by itself, an image can be displayed without a backlight unit providing light to the display panel.

The above information disclosed in this Background section is only for enhancement of understanding of the background and therefore the information discussed in this Background section does not necessarily constitute prior art.

### SUMMARY

Aspects of the present disclosure provide a display device capable of minimizing or reducing an afterimage of a product by reducing deterioration of a light emitting element.

Aspects of the present disclosure also provide a display device in which a light emitting layer or cathode electrode is formed separately for each emission area without a separate fine metal mask, and a method for fabrication thereof.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the disclosure, a display device includes a pixel circuit comprising a transistor on a substrate comprising an emission area and a non-emission area; an anode electrode located on the emission area of the substrate; a pixel defining layer located on the non-emission area of the substrate and defining a first opening; a bank structure located on the pixel defining layer and defining a second opening, the bank structure comprising a first bank layer and a second bank layer; a first cathode electrode located on the anode electrode, in contact with the bank structure, and electrically connected to the transistor; and a second cathode electrode spaced apart from the first cathode electrode with the pixel defining layer and the bank structure interposed therebetween, wherein the second cathode electrode is in contact with the bank structure, and the bank structure in contact with the first cathode electrode and the bank structure in contact with the second cathode electrode are spaced apart from each other with a third opening interposed therebetween, in a portion overlapping the non-emission area.

According to some embodiments, the first bank layer may comprise a first side surface facing the emission area and a second side surface opposite to the first side surface, and the second bank layer comprises a first tip protruding toward the first opening beyond the first side surface and a second tip protruding toward the third opening beyond the second side surface.

According to some embodiments, the first cathode electrode may be in contact with the first side surface of the first bank layer.

According to some embodiments, the pixel circuit may comprise an active region, a drain electrode, and a source electrode of the transistor; a gate electrode of the transistor on the active region; and a connection electrode on the gate electrode and connecting the drain electrode to the bank structure.

According to some embodiments, the first cathode electrode may be electrically connected to the drain electrode of the transistor through the first bank layer.

According to some embodiments, in plan view, the first opening may be entirely surrounded by the second opening.

According to some embodiments, in plan view, the first cathode electrode and the second cathode electrode may be entirely surrounded by the bank structure, and in plan view, the bank structure surrounding the first cathode electrode and the bank structure surrounding the second cathode electrode may be spaced apart from each other with the third opening interposed therebetween.

According to some embodiments, the first cathode electrode and the second cathode electrode may be electrically insulated from each other.

According to some embodiments, the display device may further comprise a light emitting layer located between the anode electrode and the first cathode electrode, wherein the light emitting layer is in contact with the first side surface of the first bank layer.

According to some embodiments, the first side surface and the first tip form an undercut and the second side surface and the second tip form an undercut, in a direction perpendicular to the substrate, the first tip may overlap the light emitting layer and the first cathode electrode, and the second tip may do not overlap the light emitting layer and the first cathode electrode.

According to some embodiments, the pixel defining layer may be exposed in a portion overlapping the third opening.

According to some embodiments, the first bank layer may contains aluminum, and the second bank layer contains titanium.

According to some embodiments, the display device may further comprise a first element inorganic layer located on the first cathode electrode and a second element inorganic layer located on the second cathode electrode, wherein in a portion overlapping the non-emission area, the first element inorganic layer and the second element inorganic layer may be spaced apart from each other with the third opening interposed therebetween.

According to some embodiments, the first element inorganic layer may be spaced apart from the second bank layer with a cavity interposed therebetween in a direction perpendicular to the substrate.

According to some embodiments, the display device may comprise an organic encapsulation layer located on the first element inorganic layer, wherein the organic encapsulation layer fills the cavity.

According to some embodiments, the first element inorganic layer may cover the first tip of the second bank layer, while exposing the second tip.

According to some embodiments of the present disclosure, a method for fabrication of a display device includes forming an anode electrode on a substrate comprising a transistor, and forming a pixel defining layer covering the anode electrode; forming a bank structure located on the pixel defining layer and comprising a first bank layer and a second bank layer; removing a part of the bank structure to form a first hole overlapping the anode electrode and a second hole not overlapping the anode electrode; and forming a light emitting layer, a cathode electrode, and an element inorganic layer on the anode electrode, wherein the cathode electrode is in contact with the first bank layer, and the cathode electrode is electrically connected to the transistor through the first bank layer.

According to some embodiments, in the forming of the bank structure, the second bank layer may comprise a first tip protruding toward the first hole and a second tip protruding toward the second hole beyond the first bank layer.

According to some embodiments, in the forming of the light emitting layer and the cathode electrode, the light emitting layer and the cathode electrode may be formed through a deposition and etching process without a separate fine metal mask. According to some embodiments of the present disclosure, an electronic device includes at least one display device comprising a pixel circuit having a transistor on a substrate comprising an emission area and a non-emission area; a display device housing configured to accommodate the at least one display device; and an optical member configured to magnify a display image of the at least one display device or change an optical path, wherein the at least one display device comprises: an anode electrode located on the emission area of the substrate; a pixel defining layer located on the non-emission area of the substrate and defining a first opening; a bank structure located on the pixel defining layer and defining a second opening, the bank structure comprising a first bank layer and a second bank layer; a first cathode electrode located on the anode electrode, in contact with the bank structure, and electrically connected to the transistor; and a second cathode electrode spaced apart from the first cathode electrode with the pixel defining layer and the bank structure interposed therebetween, wherein the second cathode electrode is in contact with the bank structure, and the bank structure in contact with the first cathode electrode and the bank structure in contact with the second cathode electrode are spaced apart from each other with a third opening interposed therebetween, in a portion overlapping the non-emission area.

The display device according to some embodiments has an inverted pixel structure, so that deterioration of a light emitting element may be reduced, and thus an afterimage of a product may be minimized or reduced. In addition, in the display device according to some embodiments, a bank structure has a tip protruding toward an emission area, thereby forming a light emitting layer or cathode electrode separated for each emission area without a separate fine metal mask.

However, the characteristics according to some embodiments of the present disclosure are not limited to those discussed above and various other characteristics are incorporated herein.

### BRIEF DESCRIPTION OF THE DRAWINGS

The above and other aspects and features of embodiments according to the present disclosure will become more apparent by describing in detail embodiments thereof with reference to the attached drawings, in which:

FIG. 1 is a perspective view showing a display device according to some embodiments;

FIG. 2 is a cross-sectional view illustrating a display device according to some embodiments;

FIG. 3 is a plan view illustrating a display layer of a display device according to some embodiments;

FIG. 4 is a diagram showing a pixel circuit of a display device according to some embodiments;

FIG. 5 is a plan view of a plurality of pixels located in the display area of FIG. 3;

FIG. 6 is a schematic cross-sectional view taken along the line I-I′ in FIG. 5;

FIG. 7 is an enlarged cross-sectional view of the display element layer overlapping the first emission area of FIG. 6;

FIG. 8 is an enlarged cross-sectional view of the display element layer overlapping the non-emission area located between the first emission area and the second emission area of FIG. 6;

FIG. 9 is a plan view showing the arrangement of the cathode electrode and the bank structure in FIG. 6;

FIGS. 10 to 19 are cross-sectional views sequentially showing a method of fabricating the display element layer of FIG. 6;

FIG. 20 is a drawing showing an electronic device including a display device according to some embodiments; and

FIGS. 21 and 22 are drawings illustrating a head mounted display including a display device according to some embodiments.

FIG. 23 is a block diagram of an electronic device according to one embodiment of the present disclosure.

FIG. 24 is a schematic diagram of an electronic device according to various embodiments of the present disclosure.

### DETAILED DESCRIPTION

The present invention will now be described more fully herein with reference to the accompanying drawings, in which some embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art.

It is also to be understood that when a layer is referred to as being “on” another layer or substrate, it may be directly on the other layer or substrate, or one or more intervening layers may also be present. The same reference numbers indicate the same components throughout the specification.

It is to be understood that, although the terms “first,” “second,” etc. may be used herein to describe various elements, these elements should not be limited by these terms. These terms are used to distinguish one element from another element. For instance, a first element discussed below could be termed a second element without departing from the teachings of the invention. Similarly, the second element could also be termed a first element.

Unless otherwise defined, all terms (including technical and scientific terms) used herein have the same meaning as commonly understood by one of ordinary skill in the art to which the inventive concept pertains. It is also to be understood that terms defined in commonly used dictionaries should be interpreted as having meanings consistent with the meanings in the context of the related art, and are expressly defined herein unless they are interpreted in an ideal or overly formal sense.

Hereinafter, embodiments of the present disclosure will be described in more detail with reference to the accompanying drawings.

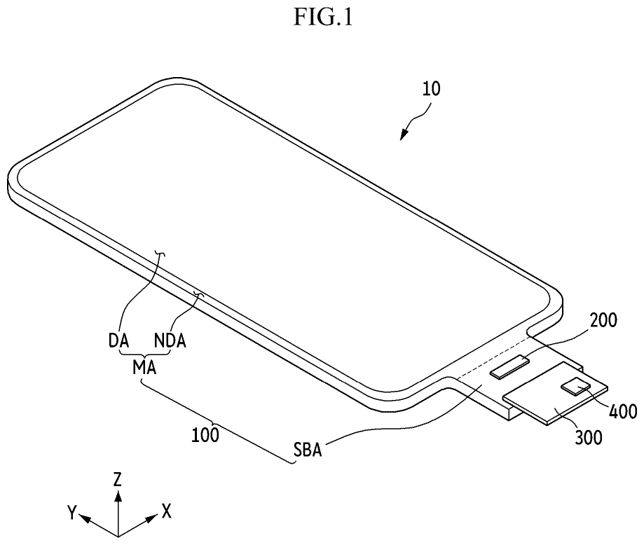

FIG. 1 is a perspective view showing a display device according to some embodiments.

Referring to FIG. 1, a display device 10 may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 may be applied as a display unit of a television, a laptop, a monitor, a billboard, or an Internet-of-Things (IoT) device. For another example, the display device 10 may be applied to wearable devices such as a smart watch, a watch phone, a glasses type display, or a head mounted display (HMD).

The display device 10 may have a planar shape similar to a quadrilateral shape. For example, the display device 10 may have a shape similar to a quadrilateral shape, in plan view, having short sides in an X-axis direction and long sides in a Y-axis direction. The corner where the short side in the X-axis direction and the long side in the Y-axis direction meet may be rounded to have a curvature (e.g., a set or predetermined curvature) or may be right-angled. The planar shape of the display device 10 is not limited to a quadrilateral shape, and may be formed in a shape similar to another polygonal shape, an irregular shape, a circular shape, or elliptical shape.

The display device 10 may include a display panel 100, a display driver 200, and a circuit board 300.

The display panel 100 may include a main region MA and a sub-region SBA. The main region MA may include the display area DA including pixels displaying images and the non-display area NDA located around (e.g., in a periphery or outside a footprint of) the display area DA.

The display area DA may emit light from a plurality of openings or a plurality of emission areas to be described later. For example, the display panel 100 may include a pixel circuit including switching elements, a pixel defining layer defining an emission area or an opening, and a self-light emitting element. For example, the self-light emitting element may include at least one of an organic light emitting diode (LED) including an organic light emitting layer, a quantum dot LED including a quantum dot light emitting layer, an inorganic LED including an inorganic semiconductor, or a micro LED, but embodiments according to the present disclosure are not limited thereto. In the following drawings, a case where the self-light emitting element is an organic light emitting diode is illustrated by way of example.

The non-display area NDA may be an area outside the display area DA. The non-display area NDA may be defined as an edge area of the main region MA of the display panel 100.

The sub-region SBA may be a region extending from one side of the main region MA. The sub-region SBA may include a flexible material which can be bent, folded or rolled. For example, when the sub-region SBA is bent, the sub-region SBA may overlap the main region MA in a thickness direction (e.g., the third direction (Z-axis direction)). The sub-region SBA may include the display driver 200 and a pad portion connected to the circuit board 300. According to some embodiments, the sub-region SBA may be omitted, and the display driver 200 and the pad portion may be located in the non-display area NDA.

The display driver 200 may output signals and voltages for driving the display panel 100. The display driver 200 may be formed as an integrated circuit (IC) and mounted on the display panel 100 by a chip on glass (COG) method, a chip on plastic (COP) method, or an ultrasonic bonding method. For example, the display driver 200 may be located in the sub-region SBA, and may overlap the main region MA in the thickness direction by bending of the sub-region SBA. For another example, the display driver 200 may be mounted on the circuit board 300.

The circuit board 300 may be attached to the pad portion of the display panel 100 by using an anisotropic conductive film (ACF). The circuit board 300 may be a flexible printed circuit board, a printed circuit board, or a flexible film such as a chip on film.

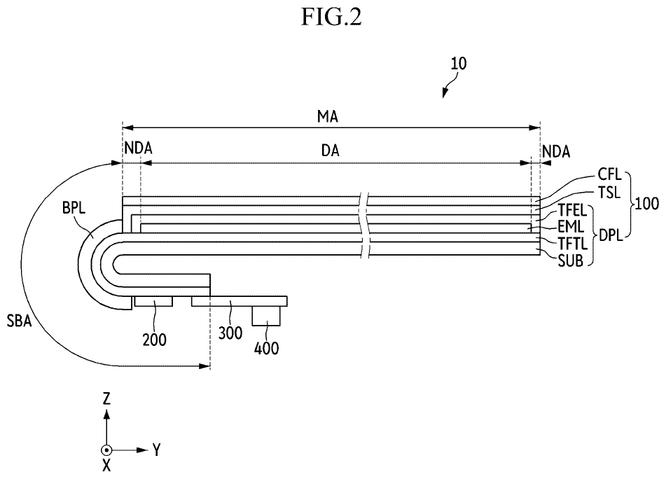

FIG. 2 is a cross-sectional view illustrating a display device according to some embodiments.

Referring to FIG. 2, the display panel 100 may include a display layer DPL, a touch sensor layer TSL, and a color filter layer CFL. The display layer DPL may include a substrate SUB, a transistor layer TFTL, a display element layer EML, and a thin film encapsulation layer TFEL.

The substrate SUB may be a base substrate or a base member. The substrate SUB may be a flexible substrate which can be bent, folded or rolled. For example, the substrate SUB may include a polymer resin such as polyimide (PI), but is not limited thereto. According to some embodiments, the substrate SUB may include a glass material or a metal material.

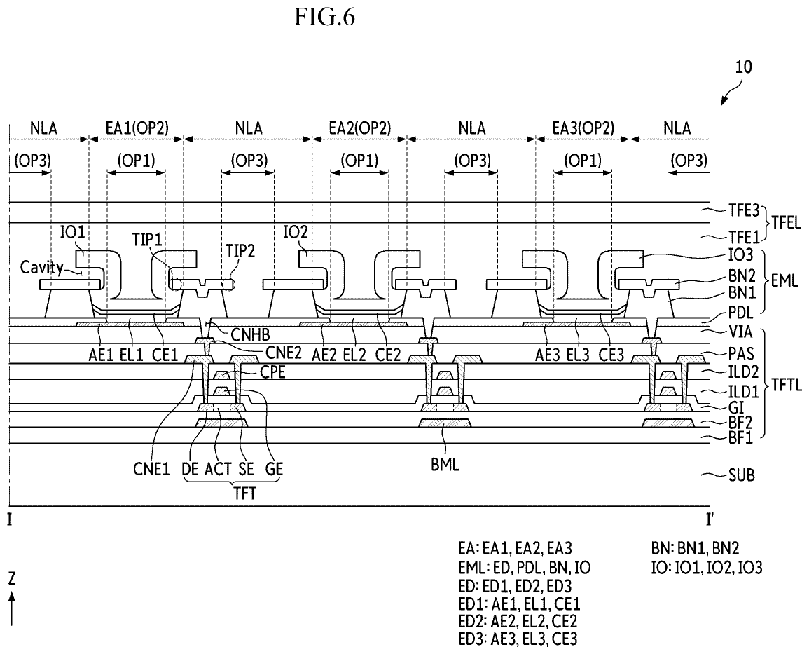

The transistor layer TFTL may be located on the substrate SUB. The transistor layer TFTL may be located in a portion overlapping the display area DA, the non-display area NDA, and the sub-region SBA. The transistor layer TFTL may include a plurality of transistors TFT (see FIG. 6).

The display element layer EML may be located on the transistor layer TFTL. The display element layer EML may be located in a portion overlapping the display area DA. The display element layer EML may include at least one of an organic light emitting diode (LED) including an organic light emitting layer, a quantum dot LED including a quantum dot light emitting layer, an inorganic LED including an inorganic semiconductor, or a micro LED, but embodiments according to the present disclosure are not limited thereto.

The thin film encapsulation layer TFEL may be located on the display element layer EML. The thin film encapsulation layer TFEL may be located in a portion overlapping the display area DA and the non-display area NDA. The thin film encapsulation layer TFEL may cover the top surface and the side surface of the display element layer EML and protect the display element layer EML from external oxygen and moisture. The thin film encapsulation layer TFEL may include at least one inorganic film and at least one organic film for encapsulating the display element layer EML.

The touch sensor layer TSL may be located on the thin film encapsulation layer TFEL. The touch sensor layer TSL may be located in a portion overlapping the display area DA and the non-display area NDA. The touch sensor layer TSL may sense the user's touch by using a mutual capacitance method or a self-capacitance method.

The color filter layer CFL may be located on the touch sensor layer TSL. The color filter layer CFL may be located in a portion overlapping the display area DA and the non-display area NDA. The color filter layer CFL may absorb a part of light coming from the outside of the display device 10 to reduce reflected light due to external light. Accordingly, the color filter layer CFL may prevent or reduce color distortion caused by reflection of the external light.

Because the color filter layer CFL is directly located on the touch sensor layer TSL, the display device 10 may not require a separate substrate for the color filter layer CFL. Accordingly, the thickness of the display device 10 may be relatively small. The color filter layer CFL may be omitted according to some embodiments.

As illustrated in FIG. 2, a portion of the display panel 100 overlapping the sub-region SBA may be bent. When a portion of the display panel 100 is bent, the display driver 200, the circuit board 300, and the touch driver 400 may overlap the main region MA in the third direction (Z-axis direction).

When a portion of the display panel 100 is bent, a bending protection layer BPL may protect the lower structure located to overlap the sub-region SBA from bending stress.

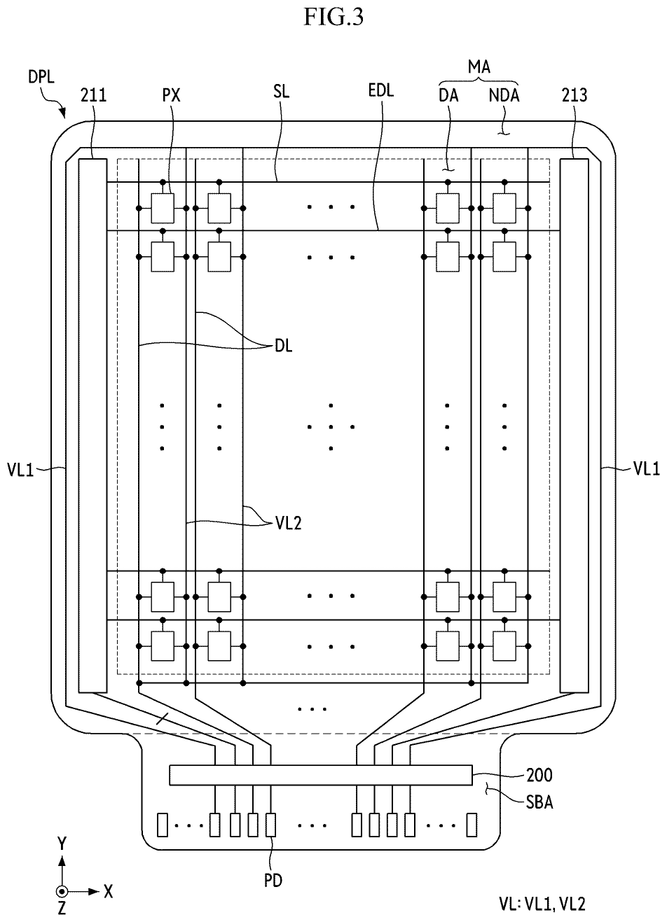

FIG. 3 is a plan view illustrating a display layer of a display device according to some embodiments.

Referring to FIG. 3, the display layer DPL may include a plurality of pixels PX in a portion overlapping the display area DA, a plurality of power lines VL connected to the plurality of pixels PX, a plurality of scan lines SL, a plurality of emission control lines EDL, and a plurality of data lines DL.

Each of the plurality of scan lines SL may extend in the first direction (X-axis direction) and may be spaced apart from each other in the second direction (Y-axis direction) intersecting the first direction (X-axis direction). The scan lines SL may be arranged along the second direction (Y-axis direction). The scan lines SL may sequentially supply a scan signal to the plurality of pixels PX.

The emission control lines EDL may each extend in the first direction (X-axis direction) and may be spaced apart from each other in the second direction (Y-axis direction). The emission control lines EDL may be arranged along the second direction (Y-axis direction). The emission control lines EDL may sequentially supply an emission signal to the plurality of pixels PX.

The data lines DL may extend in the second direction (Y-axis direction) and may be spaced apart from each other in the first direction (X-axis direction). The data lines DL may be arranged along the first direction (X-axis direction). The data lines DL may supply data voltages to the plurality of pixels PX. The data voltage may determine the luminance of each of the pixels PX.

The power lines VL may each extend in the second direction (Y-axis direction) and may be spaced apart from each other in the first direction (X-axis direction). The power lines VL may be arranged along the first direction (X-axis direction). The power lines VL may supply a first power voltage VDL and/or a second power voltage VSL to the plurality of pixels PX.

The power line VL may include a main power line VL1 and a sub-power line VL2. Either the first power voltage VDL or the second power voltage VSL may be transmitted to the sub-power line VL2 through the main power line VL1 overlapping the non-display area NDA. Hereinafter, the main power line VL1 and the sub-power line VL2 may be collectively referred to as the power line VL.

The non-display area NDA may surround (e.g., in a periphery or outside a footprint of) the display area DA. The non-display area NDA may include a scan driver 211 and an emission control driver 213.

The scan driver 211 may be located outside one side of the display area DA or on one side of the non-display area NDA. The scan driver 211 may include a plurality of driving transistors that generate gate signals based on a gate control signal.

The emission control driver 213 may be located outside the other side of the display area DA or on the other side of the non-display area NDA. The emission control driver 213 may include a plurality of emission control transistors that generate emission signals based on the emission control signal.

The display layer DPL according to some embodiments may include the display driver 200 and a plurality of pad electrodes PD in a portion overlapping the sub-region SBA. The plurality of pad electrodes PD may be spaced apart from each other in the first direction (X-axis direction), and the pad electrodes PD may be connected to different wires, respectively.

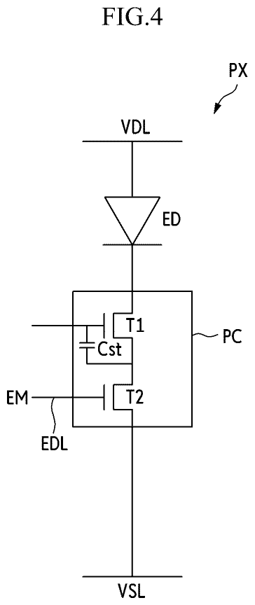

FIG. 4 is a diagram showing a pixel circuit of a display device according to some embodiments. Although FIG. 4 illustrates various components in a pixel circuit according to some embodiments, embodiments according to the present disclosure are not limited thereto, and according to some embodiments the pixel circuit may have additional components or fewer components without departing from the spirit and scope of embodiments according to the present disclosure.

Referring to FIG. 4 in addition to FIG. 3, the pixel PX may include a pixel circuit PC and a light emitting element ED. The pixel circuit PC may control the light emitting timing and luminance of the light emitting element ED by controlling the driving current supplied to the light emitting element ED.

The light emitting element ED according to some embodiments may be connected between the first power voltage VDL and the pixel circuit PC. The light emitting element ED, which is a light source of the pixel PX, may emit light in response to a driving current supplied from the pixel circuit PC.

The light emitting element ED may be an organic light emitting diode, but embodiments according to the present disclosure are not limited thereto. For example, the light emitting element ED may be an inorganic light emitting element, a quantum dot light emitting element, or another type of light emitting element.

The pixel circuit PC according to some embodiments may include at least one first transistor T1, at least one second transistor T2, and at least one capacitor Cst.

The first transistor T1 according to some embodiments may be a driving transistor that supplies a driving current to the light emitting element ED. The first transistor T1 may control the driving current flowing between the first electrode and the second electrode according to the data voltage applied through the data line DL. For example, the first electrode may be any one of a source electrode or a drain electrode, and the second electrode may be any one of a source electrode or a drain electrode.

The second transistor T2 according to some embodiments may be an emission control transistor connected to the emission control line EDL. The second transistor T2 may be turned on by an emission signal EM, and thus a current may flow to the light emitting element ED. The first electrode of the second transistor T2 may be connected to the first transistor T1, and the second electrode thereof may be connected to the second power voltage VSL.

The capacitor Cst may be connected to the first transistor T1 to control the capacitance and current and to stabilize the voltage of the first transistor T1.

The pixel PX according to some embodiments may have an inverted pixel structure. In other words, the aforementioned first transistor T1 and/or second transistor T2 may be an n-type MOSFET (NMOS) transistor including an oxide-based active layer.

Generally, the transistor including the oxide-based active layer may have a coplanar structure in which a gate electrode is located thereon. The transistor including the oxide-based active layer may output a current flowing into the drain electrode to the source electrode based on a gate high voltage applied to the gate electrode.

For example, a transistor including an oxide-based active layer may have excellent leakage current prevention characteristics and may be driven at low frequencies, thereby reducing power consumption. Accordingly, the display device 10 according to some embodiments may reduce or prevent the likelihood of the leakage current flowing in the pixel PX, maintain the voltage in the pixel stably, and reduce deterioration of the light emitting element ED, so that an afterimage of a product may be minimized or reduced.

The light emitting element ED according to some embodiments may include an anode electrode AE (see FIG. 6), a light emitting layer EL (see FIG. 6), and a cathode electrode CE (see FIG. 6). According to some embodiments, the anode electrode AE (see FIG. 6) of the light emitting element ED may be electrically connected to the first power voltage VDL. For example, the first power voltage VDL may be a high potential driving voltage. In addition, the cathode electrode CE (see FIG. 6) of the light emitting element ED may be connected to any one of the first transistor T1 and/or the second transistor T2 to be electrically connected to the second power voltage VSL. For example, the second power voltage VSL may be a low potential driving voltage.

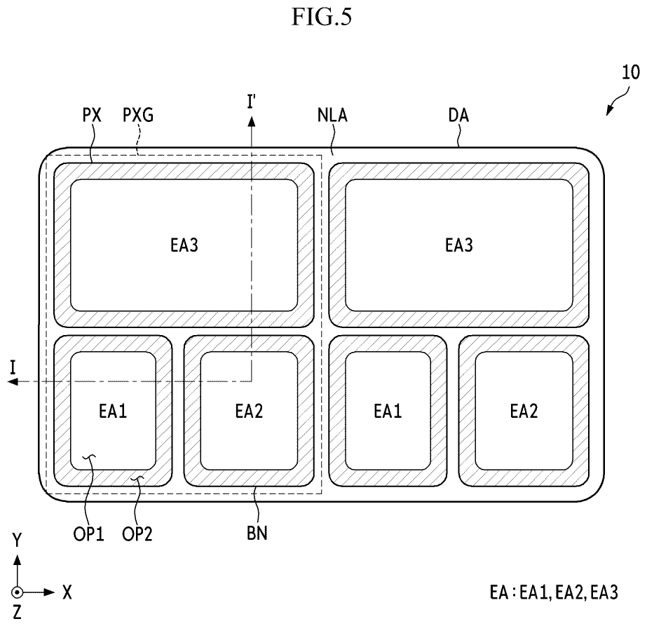

FIG. 5 is a plan view of a plurality of pixels located in the display area of FIG. 3.

Referring to FIG. 5, the display area DA included in the display device 10 according to some embodiments may include the emission area EA and a non-emission area NLA. The emission area EA may include a first emission area EA1, a second emission area EA2, and a third emission area EA3 that are spaced apart from each other. The non-emission area NLA may surround each of the first emission area EA1, the second emission area EA2, and the third emission area EA3. The non-emission area NLA may assist in preventing the respective lights emitted from the first emission area EA1, the second emission area EA2, and the third emission area EA3 from being mixed.

The first emission area EA1, the second emission area EA2, and the third emission area EA3 may emit light of different colors. The color of light emitted from each of the first emission area EA1, the second emission area EA2, and the third emission area EA3 may be different according to the type of the light emitting element ED (see FIG. 5) which will be described later. For example, the first emission area EA1 may emit red light of a first color, the second emission area EA2 may emit green light of a second color, and the third emission area EA3 may emit green light of a third color, but embodiments according to the present disclosure are not limited thereto. The sizes and shapes of the first emission area EA1, the second emission area EA2, and the third emission area EA3 may be freely adjusted according to required characteristics.

In some embodiments, the pixel PX having at least one first emission area EA1, the pixel PX having at least one second emission area EA2, and the pixel PX having at least one third emission area EA3 may constitute one pixel group PXG. The pixel group PXG may be a minimum unit that emits white light. However, the type and/or number of each of the first emission area EA1, the second emission area EA2, and the third emission area EA3 constituting the pixel group PXG may vary according to the embodiments.

The emission area EA may be defined by a first opening OP1 and a second opening OP2. The first opening OP1 may be defined by a pixel defining layer PDL (see FIG. 6), and the second opening OP2 may be defined by a bank structure BN. In plan view, the second opening OP2 may completely surround the first opening OP1.

The bank structure BN surrounding each first emission area EA1, the TFT

BN surrounding each second emission area EA2, and the bank structure BN surrounding each third emission area EA3 may be spaced apart and insulated from each other in plan view.

FIG. 6 is a schematic cross-sectional view taken along the line I-I′ in FIG. 5. FIG. 6 shows a cross-sectional structure of the display layer DPL of the display device 10 according to some embodiments.

Referring to FIG. 6, the transistor layer TFTL may be located on the substrate SUB. The transistor layer TFTL may include a first buffer layer BF1, a lower metal layer BML, a second buffer layer BF2, a transistor TFT, a gate insulating layer GI, a first insulating layer ILD1, a capacitor electrode CPE, a second insulating layer ILD2, a first connection electrode CNE1, a passivation layer PAS, a second connection electrode CNE2, and a via layer VIA.

The first buffer layer BF1 may be located on the substrate SUB. The first buffer layer BF1 may include an inorganic film capable of preventing or reducing penetration of air, moisture, or other contaminants. For example, the first buffer layer BF1 may include a plurality of inorganic films alternately stacked.

The lower metal layer BML may be located on the first buffer layer BF1. For example, the lower metal layer BML may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The second buffer layer BF2 may cover the first buffer layer BF1 and the lower metal layer BML. The second buffer layer BF2 may include an inorganic film capable of preventing or reducing penetration of air, moisture, or other contaminants. For example, the second buffer layer BF2 may include a plurality of inorganic films alternately stacked.

The transistor TFT may be located on the second buffer layer BF2, and may constitute a pixel circuit of each of the plurality of pixels. For example, the transistor TFT may be a switching transistor or a driving transistor of the pixel circuit. The transistor TFT according to some embodiments may include an oxide semiconductor containing indium (In).

The transistor TFT may include an active layer ACT, a source electrode SE, a drain electrode DE, and a gate electrode GE. The active layer ACT may be located on the second buffer layer BF2. The active layer ACT may overlap the gate electrode GE in the third direction (Z-axis direction), and may be insulated from the gate electrode GE by the gate insulating layer GI. In a part of the active layer ACT, a material of the active layer ACT may be made into a conductor to form the source electrode SE and the drain electrode DE.

The gate electrode GE may be located on the gate insulating layer GI. The gate electrode GE may overlap the active layer ACT with the gate insulating layer GI interposed therebetween.

The gate insulating layer GI may be located on the active layer ACT. The gate insulating layer GI may cover the active layer ACT and the second buffer layer BF2 to insulate the gate electrode GE from the active layer ACT. The gate insulating layer GI may include a contact hole through which the first connection electrode CNE1 passes.

The first insulating layer ILD1 may cover the gate electrode GE and the gate insulating layer GI. The first insulating layer ILD1 may include a contact hole through which the first connection electrode CNE1 passes. The contact hole of the first insulating layer ILD1 may be connected to the contact hole of the gate insulating layer GI and the contact hole of the second insulating layer ILD2.

The capacitor electrode CPE may be located on the first insulating layer ILD1. The capacitor electrode CPE may overlap the gate electrode GE in the third direction (Z-axis direction). The capacitor electrode CPE and the gate electrode GE may form a capacitance.

The second insulating layer ILD2 may cover the capacitor electrode CPE and the first insulating layer ILD1. The second insulating layer ILD2 may include a contact hole through which the first connection electrode CNE1 passes. The contact hole of the second insulating layer ILD2 may be connected to the contact hole of the first insulating layer ILD1 and the contact hole of the gate insulating layer GI.

The first connection electrode CNE1 may be located on the second insulating layer ILD2. The first connection electrode CNE1 may electrically connect the drain electrode DE of the transistor TFT to the second connection electrode CNE2. The first connection electrode CNE1 may be inserted into a contact hole provided in the first insulating layer ILD1, the second insulating layer ILD2, and the gate insulating layer GI to be in contact with the drain electrode DE of the transistor TFT.

The passivation layer PAS may cover the first connection electrode CNE1 and the second insulating layer ILD2. The passivation layer PAS may flatten the lower structure. The passivation layer PAS may include a contact hole through which the second connection electrode CNE2 passes.

The passivation layer PAS may contain an organic insulating material. For example, the passivation layer PAS may include acrylic resin, polyimide, polyamide, benzocyclobutene, phenol resin, and the like.

The second connection electrode CNE2 may be located on the passivation layer PAS. The second connection electrode CNE2 may be inserted into a contact hole formed in the passivation layer PAS to be in contact with the first connection electrode CNE1. The second connection electrode CNE2 may electrically connect the first connection electrode CNE1 to the anode electrode AE.

The via layer VIA may cover the second connection electrode CNE2 and the passivation layer PAS. The via layer VIA may include a contact hole through which the anode electrode AE passes.

The via layer VIA may include an organic material. For example, the via layer VIA may include acrylic resin, polyimide, polyamide, benzocyclobutene, phenol resin, and the like.

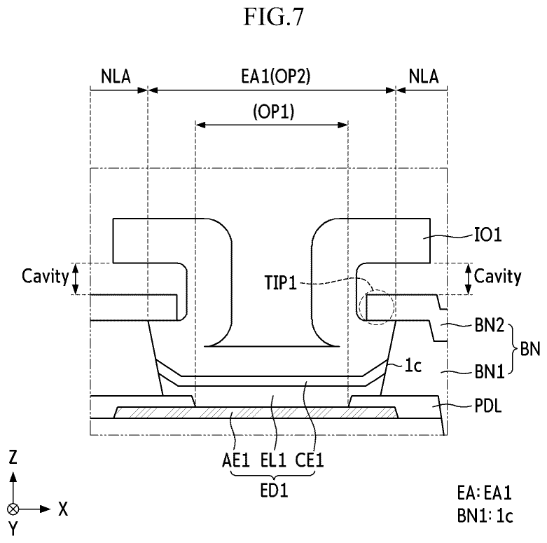

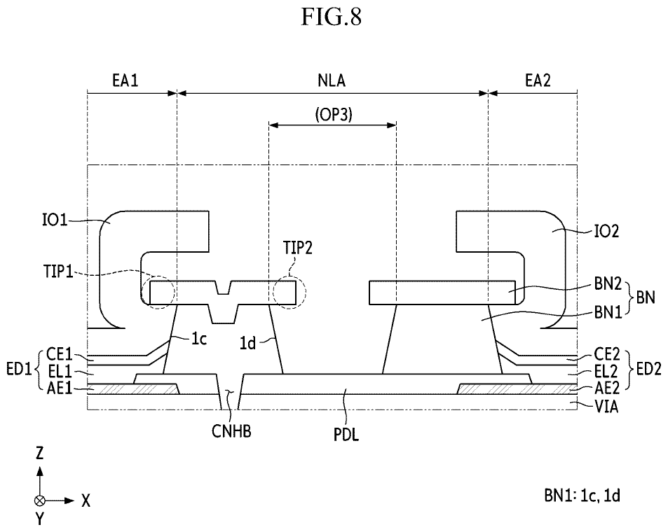

FIG. 7 is an enlarged cross-sectional view of the display element layer overlapping the first emission area of FIG. 6. FIG. 8 is an enlarged cross-sectional view of the display element layer overlapping the non-emission area located between the first emission area and the second emission area of FIG. 6.

Referring to FIGS. 6 to 8, the display element layer EML may be located on the transistor layer TFTL. The display element layer EML may include the light emitting element ED, the pixel defining layer PDL, the bank structure BN, and an element inorganic layer IO.

The light emitting element ED according to some embodiments may include a first light emitting element ED1 located in the first emission area EA1, a second light emitting element ED2 located in the second emission area EA2, and a third light emitting element ED3 located in the third emission area EA3.

The first light emitting element ED1 may include the first anode electrode AE1, a first light emitting layer EL1, and a first cathode electrode CE1, the second light emitting element ED2 may include the second anode electrode AE2, a second light emitting layer EL2, and a second cathode electrode CE2, and the third light emitting element ED3 may include the third anode electrode AE3, a third light emitting layer EL3, and a third cathode electrode CE3.

The first light emitting element ED1, the second light emitting element ED2, and the third light emitting element ED3 may emit light of different colors according to the material of the light emitting layer EL contained therein. For example, the first light emitting element ED1 may emit red light, the second light emitting element ED2 may emit green light, and the third light emitting element ED3 may emit blue light.

The anode electrode AE according to some embodiments may be located on the via layer VIA. The anode electrode AE may overlap the emission area EA. As described above, the anode electrode AE may receive the first power voltage VDL of FIG. 4.

The anode electrode AE may include a transparent electrode material or/and a conductive metal material. For example, the anode electrode AE may contain one or more of silver (Ag), copper (Cu), aluminum (Al), nickel (Ni), lanthanum (La), titanium (Ti), and titanium nitride (TiN). Alternatively, the anode electrode AE may contain one or more of indium tin oxide (ITO), indium zinc oxide (IZO), and indium tin zinc oxide (ITZO). According to some embodiments, the anode electrode AE may have a multilayer structure having a metal material layer and a transparent electrode material layer.

The anode electrode AE may include the first anode electrode AE1 located in the first emission area EA1, the second anode electrode AE2 located in the second emission area EA2, and the third anode electrode AE3 located in the third emission area EA3. The first anode electrode AE1, the second anode electrode AE2, and the third anode electrode AE3 may be located to be spaced apart from each other on the via layer VIA.

The pixel defining layer PDL according to some embodiments may be located on the via layer VIA in a portion overlapping the non-emission area NLA. The pixel defining layer PDL may define the first opening OP1 and expose a part of the anode electrode AE in a portion overlapping the first opening OP1. In other words, the pixel defining layer PDL may cover the edge of the anode electrode AE.

The pixel defining layer PDL may include an inorganic insulating material. For example, the pixel defining layer PDL may include any one of aluminum oxide, titanium oxide, tantalum oxide, hafnium oxide, zinc oxide, silicon oxide, silicon nitride, and silicon oxynitride.

The bank structure BN according to some embodiments may be located on the pixel defining layer PDL at a portion overlapping the non-emission area NLA. The bank structure BN may define the second opening OP2 and may surround the light emitting element ED. For example, the bank structure BN may surround the first light emitting element ED1 in a portion overlapping the first emission area EA1, arranged to surround the second light emitting element ED2 in a portion overlapping the second emission area EA2, and arranged to surround the third light emitting element ED3 in a portion overlapping the third emission area EA3. The bank structure BN surrounding the first light emitting element ED1, the bank structure BN surrounding the second light emitting element ED2, and the bank structure BN surrounding the third light emitting element ED3 may be spaced apart from each other.

The bank structure BN may include a first bank layer BN1 and a second bank layer BN2 containing different metal materials and structures.

According to some embodiments, the first bank layer BN1 may be located on the pixel defining layer PDL. The first bank layer BN1 may include a metal with high electrical conductivity. As an example, the first bank layer BN1 may include aluminum (Al).

The first bank layer BN1 may be formed to fill a bank contact hole CNHB that penetrates the pixel defining layer PDL and the via layer VIA. Accordingly, the first bank layer BN1 may be electrically connected to the second connection electrode CNE2 through the bank contact hole CNHB.

The first bank layer BN1 may be in contact with the cathode electrode CE to be electrically connected to the cathode electrode CE. Therefore, the cathode electrode CE may be electrically connected to the second connection electrode CNE2 via the first bank layer BN1, and may be connected to the drain electrode DE of the transistor TFT via the first connection electrode CNE1 and the second connection electrode CNE2.

In some embodiments, the first bank layer BN1 may include a first side surface 1c and a second side surface 1d. The first side surface 1c may be a surface facing the first opening OP1, and the second side surface 1d may be a surface facing the third opening OP3. The first side surface 1c and the second side surface 1d may be opposite to each other.

The second bank layer BN2 according to some embodiments may be positioned on the first bank layer BN1. The second bank layer BN2 may include a material with a lower etching rate than the first bank layer BN1. As an example, the second bank layer BN2 may contain titanium (Ti). The second bank layer BN2 may have a lower height than that of the first bank layer BN1.

The second bank layer BN2 may include a first tip TIP1 protruding in a direction toward the first opening OP1 beyond the first side surface 1c of the first bank layer BN1 and a second tip TIP2 protruding in a direction toward the third opening OP3 beyond the second side surface 1d of the first bank layer BN1. The first tip TIP1 and the second tip TIP2 of the second bank layer BN2 may be formed according to different etching rates of the first bank layer BN1 and the second bank layer BN2 in the fabrication process of the display device 10. Undercut shapes may be formed between the first tip TIP1 of the second bank layer BN2 and the first side surface 1c of the first bank layer BN1 and between the second tip TIP2 of the second bank layer BN2 and the second side surface 1d of the first bank layer BN1. The fabrication process will be described later.

In general, a high-resolution display device may have a relatively narrow gap between the neighboring light emitting elements ED. Therefore, in the fabrication process, it may be difficult to form the plurality of light emitting elements ED included in the high-resolution display device using a mask.

In the display device 10 according to some embodiments, because the bank structure BN includes the first tip TIP1, the first light emitting element ED1, the second light emitting element ED2, and the third light emitting element ED3 may be formed to overlap the first emission area EA1, the second emission area EA2, and the third emission area EA3, respectively, without a separate fine metal mask in the fabrication process. The fabrication process will be described later.

The light emitting layer EL according to some embodiments may be located on the anode electrode AE. The light emitting layer EL may be an organic light emitting layer made of an organic material, and may be formed on the anode electrode AE by the deposition process. In the display device 10 according to some embodiments, as the first power voltage VDL (see FIG. 4) is applied to the anode electrode AE and the transistor TFT applies a voltage (e.g., a set or predetermined voltage) to the cathode electrode CE, holes and electrons may move to the light emitting layer EL through a hole transport layer and an electron transport layer, respectively, and the holes and electrons may combine with each other in the light emitting layer EL to emit light.

The light emitting layer EL may include the first light emitting layer EL1, the second light emitting layer EL2, and the third light emitting layer EL3 located in the first emission area EA1, the second emission area EA2, and the third emission area EA3, respectively. The first light emitting layer EL1 may be located on the first anode electrode AE1 in the first emission area EA1, the second light emitting layer EL2 may be located on the second anode electrode AE2 in the second emission area EA2, and the third light emitting layer EL3 may be located on the third anode electrode AE3 in the third emission area EA3.

The first light emitting layer EL1, the second light emitting layer EL2, and the third light emitting layer EL3 may emit different colors. For example, the first light emitting layer EL1 may emit red light, the second light emitting layer EL2 may emit green light, and the third light emitting layer EL3 may emit blue light.

The light emitting layer EL may be in contact with the first side surface 1c of the first bank layer BN1 and may cover the pixel defining layer PDL in a portion overlapping the second opening OP2.

The cathode electrode CE according to some embodiments may be located on the light emitting layer EL. The cathode electrode CE may include a transparent conductive material, so that the light generated in the light emitting layer EL may be emitted. As described above, the cathode electrode CE may receive a voltage (e.g., a set or predetermined voltage) through the transistor TFT.

The cathode electrode CE may include the first cathode electrode CE1, the second cathode electrode CE2, and the third cathode electrode CE3 respectively located in the first emission area EA1, the second emission area EA2, and the third emission area EA3. The first cathode electrode CE1 may be located on the first light emitting layer EL1 in the first emission area EA1, the second cathode electrode CE2 may be located on the second light emitting layer EL2 in the second emission area EA2, and the third cathode electrode CE3 may be located on the third light emitting layer EL3 in the third emission area EA3. The first cathode electrode CE1, the second cathode electrode CE2, and the third cathode electrode CE3 may be spaced apart from each other with the bank structure BN interposed therebetween.

The cathode electrode CE may be in contact with the first side surface 1c of the first bank layer BN1 and may cover the pixel defining layer PDL in a portion overlapping the second opening OP2.

In the fabrication process of the display device 10, the step coverage in the process of forming the cathode electrode CE may be higher than the step coverage in the process of forming the light emitting layer EL. Thus, the cathode electrode CE may entirely cover the light emitting layer EL. The fabrication process will be described later.

According to some embodiments, the element inorganic layer IO may be located on the light emitting element ED. The element inorganic layer IO covers the light emitting element ED, thereby reducing or preventing instances of contaminants such as oxygen or moisture penetrating into the light emitting element ED.

The element inorganic layer IO may contain an inorganic insulating material. For example, the element inorganic layer IO may contain any one of silicon nitride, silicon oxide, and silicon oxynitride.

The element inorganic layer IO may include a first element inorganic layer IO1, a second element inorganic layer IO2, and a third element inorganic layer IO3. The first element inorganic layer IO1 may be located on the first light emitting element ED1 in the first emission area EA1, the second element inorganic layer IO2 may be located on the second light emitting element ED2 in the second emission area EA2, and the third element inorganic layer IO3 may be located on the third light emitting element ED3 in the third emission area EA3. The first element inorganic layer IO1, the second element inorganic layer IO2, and the third element inorganic layer IO3 may be spaced apart from each other in a portion overlapping the non-emission area NLA.

The element inorganic layer IO (e.g., the first element inorganic layer IO1) may be in overall contact with the light emitting element ED to cover it in a portion overlapping the first opening OP1, and may be in contact with the first side surface 1c of the first bank layer BN1 to cover it in a portion overlapping the second opening OP2.

In some embodiments, the element inorganic layer IO may cover the first tip TIP1 of the bank structure BN. In the drawing, the element inorganic layer IO is shown as not being in contact with the first tip TIP1 of the bank structure BN, but embodiments according to the present disclosure are not limited thereto. According to some embodiments, the element inorganic layer IO may be in contact with the first tip TIP1 of the bank structure BN.

The element inorganic layer IO may be spaced apart from the second bank layer BN2 in the third direction (Z-axis direction) in a portion overlapping the second opening OP2 and the non-emission area NLA. In other words, the element inorganic layer IO may be spaced apart from the second bank layer BN2 with a cavity interposed therebetween in the third direction (Z-axis direction), in a portion overlapping the second opening OP2 and the non-emission area NLA. The cavity may be formed in a portion overlapping the first tip TIP1 of the second bank layer BN2.

In the fabrication process of the display device 10, the cavity may be formed by temporarily depositing the material forming the light emitting layer EL and the material forming the cathode electrode CE on the second bank layer BN2, and then removing them by a subsequent etching process after the element inorganic layer IO is formed. The fabrication process will be described later.

The bank structures BN respectively located in portions adjacent to the first emission area EA1, the second emission area EA2, and the third emission area EA3 may be spaced apart and insulated from each other with the third openings OP3 interposed therebetween. Accordingly, the first cathode electrode CE1, the second cathode electrode CE2, and the third cathode electrode CE3, which respectively overlap the first emission area EA1, the second emission area EA2, and the third emission area EA3, may be insulated from each other.

In a portion overlapping the non-emission area NLA, the bank structure BN arranged to overlap the bank contact hole CNHB may include a stepped portion. In the fabrication process of the display device 10, the first bank layer BN1 may be deposited to fill the bank contact hole CNHB. Accordingly, the first bank layer BN1 and the second bank layer BN2 located in a portion overlapping the bank contact hole CNHB may include stepped portions corresponding to the shape of the bank contact hole CNHB. In contrast, the first bank layer BN1 and the second bank layer BN2 located in a portion not overlapping the bank contact hole CNHB may have flat surfaces. In other words, the bank structure BN may have a different shape depending on whether it overlaps the bank contact hole CNHB or not.

In a portion overlapping the non-emission area NLA, the element inorganic layer IO may expose the second tip TIP2 of the second bank layer BN2. Accordingly, the second tip TIP2 of the second bank layer BN2 may be entirely covered by an organic encapsulation layer TFE1.

The second tip TIP2 of the second bank layer BN2 may be located in a portion overlapping the third opening OP3, and the pixel defining layer PDL overlapping the third opening OP3 may be exposed.

The thin film encapsulation layer TFEL according to some embodiments may be located on the display element layer EML. The thin film encapsulation layer TFEL may include the organic encapsulation layer TFE1 and an inorganic encapsulation layer TFE3.

The organic encapsulation layer TFE1 according to some embodiments may be located on the element inorganic layer IO. For example, the organic encapsulation layer TFE1 may be in overall contact with the first element inorganic layer IO1, the second element inorganic layer IO2, and the third element inorganic layer IO3 to cover them.

The organic encapsulation layer TFE1 may flatten the stepped portion formed according to the profile of the lower structure and fill the cavity formed between the second bank layer BN2 and the element inorganic layer IO.

The organic encapsulation layer TFE1 may include a polymer-based material. For example, the organic encapsulation layer TFE1 may include acrylic resin, silicone resin, epoxy resin, silicone acrylic resin, polyimide, polyethylene, and the like.

According to some embodiments, the inorganic encapsulation layer TFE3 may be located on the organic encapsulation layer TFE1. The inorganic encapsulation layer TFE3 may protect the lower structure from permeation of moisture and oxygen.

The inorganic encapsulation layer TFE3 may contain an inorganic insulating material. For example, the inorganic encapsulation layer TFE3 may contain any one of silicon nitride, silicon oxide, and silicon oxynitride.

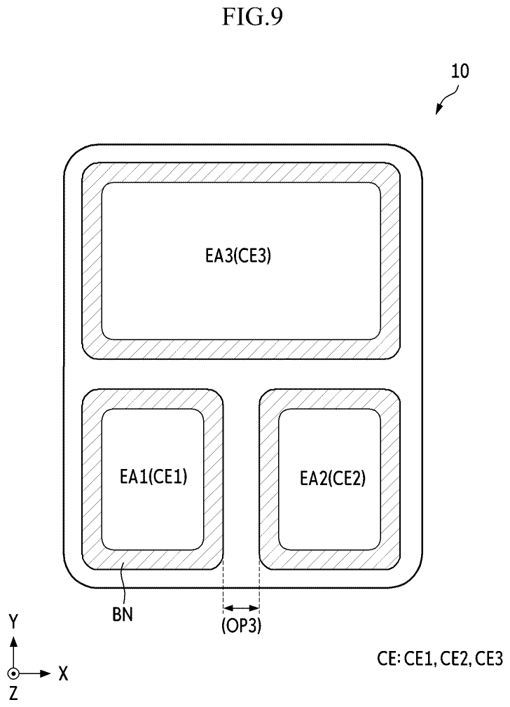

FIG. 9 is a plan view showing the arrangement of the cathode electrode and the bank structure in FIG. 6.

Referring to FIG. 9, the first cathode electrode CE1, the second cathode electrode CE2, and the third cathode electrode CE3 according to some embodiments may be located to be spaced apart from each other in portions overlapping the first emission area EA1, the second emission area EA2 and the third emission area EA3, respectively, in plan view.

The first cathode electrode CE1, the second cathode electrode CE2, and the third cathode electrode CE3 may be surrounded by each bank structure BN in plan view. The bank structures BN arranged to respectively surround the first cathode electrode CE1, the second cathode electrode CE2, and the third cathode electrode CE3 may be spaced apart from each other with the third openings OP3 interposed therebetween in plan view. In other words, the first cathode electrode CE1, the second cathode electrode CE2, and the third cathode electrode CE3 may be insulated from each other. Further, the bank structures BN arranged to surround the first cathode electrode CE1, the second cathode electrode CE2, and the third cathode electrode CE3 may also be insulated from each other.

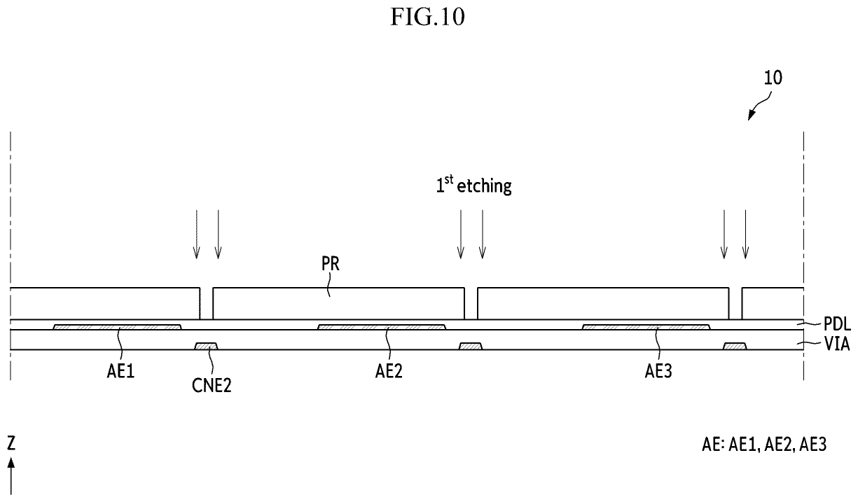

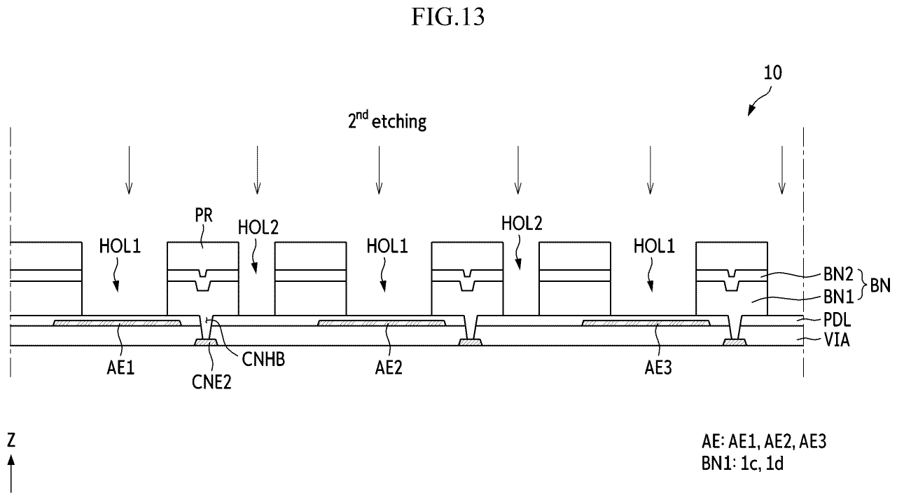

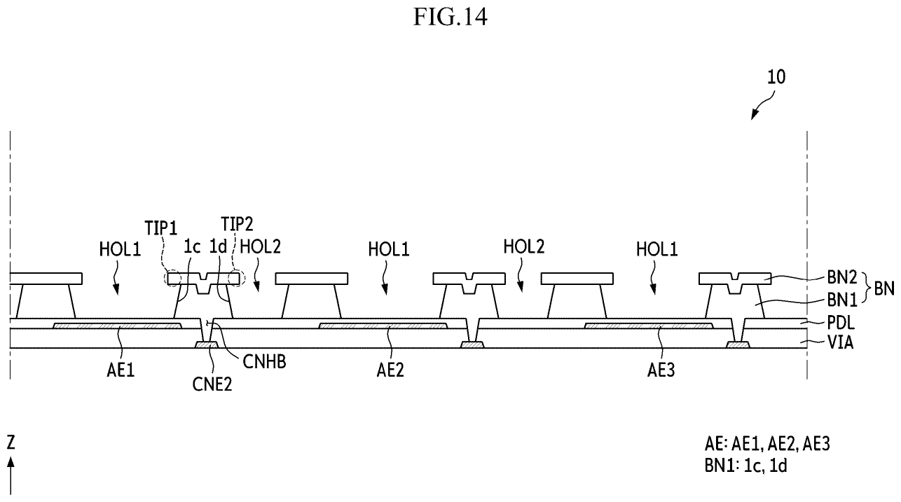

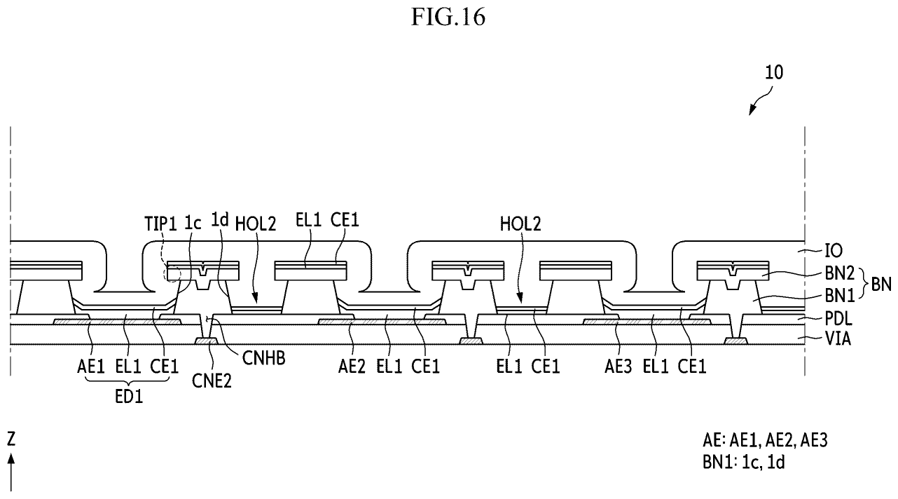

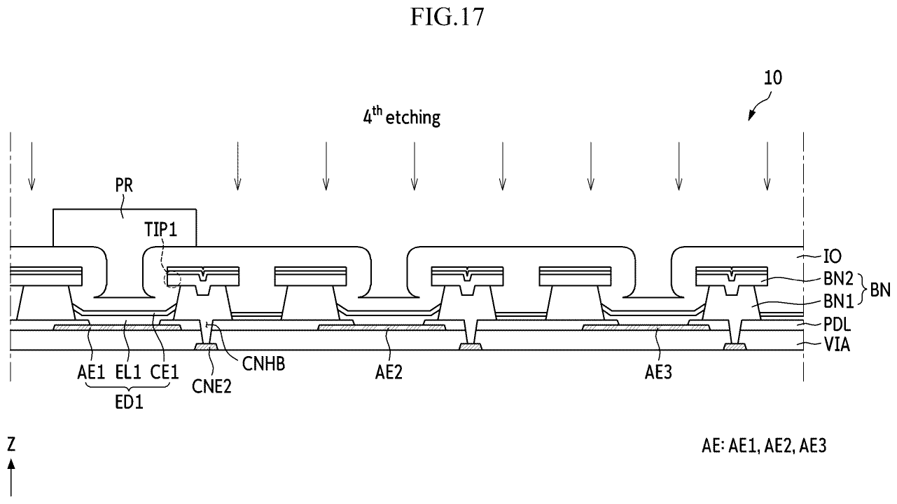

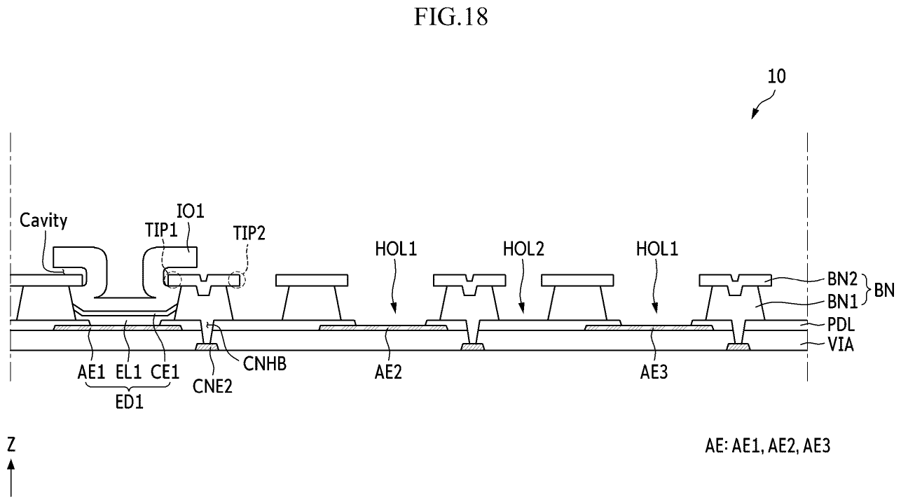

FIGS. 10 to 19 are cross-sectional views sequentially showing a method of fabricating the display element layer of FIG. 6.

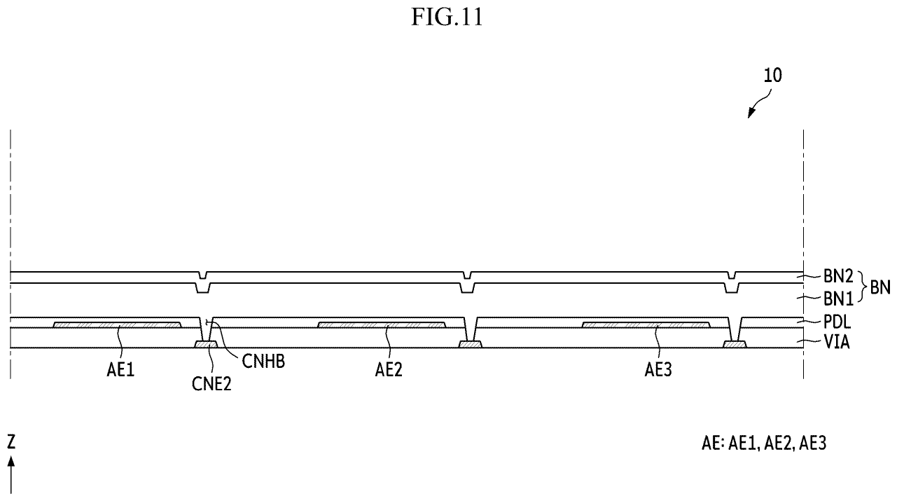

Referring to FIGS. 10 and 11, after forming a plurality of anode electrodes AE on the via layer VIA covering the second connection electrode CNE2, the pixel defining layer PDL is formed to entirely cover the anode electrode AE.

The anode electrode AE may include the first anode electrode AE1, the second anode electrode AE2, and the third anode electrode AE3. The first anode electrode AE1, the second anode electrode AE2 and the third anode electrode AE3 may be spaced apart from each other. The via layer VIA, the anode electrode AE, and the pixel defining layer PDL according to some embodiments may include the aforementioned materials. Some redundant descriptions may be omitted.

Then, a plurality of photoresists PR are formed on the pixel defining layer PDL. The plurality of photoresists PR may be spaced apart from each other. Subsequently, a first etching process (1^{st} etching) is performed using the plurality of photoresists PR as a mask to form the bank contact hole CNHB. The bank contact hole CNHB may be formed by removing a part of the via layer VIA and a part of the pixel defining layer PDL.

In this process, the second connection electrode CNE2 may be partially exposed by the bank contact hole CNHB.

Next, the bank structure BN is formed on the entire pixel defining layer PDL. The bank structure BN may include the first bank layer BN1 and the second bank layer BN2. In this process, the first bank layer BN1 may be formed to fill the bank contact hole CNHB. Accordingly, the first bank layer BN1 may be in contact with the second connection electrode CNE2 to be electrically connected to the second connection electrode CNE2.

In this process, the first bank layer BN1 and the second bank layer BN2 may cover the stepped portion of the bank contact hole CNHB. Accordingly, the first bank layer BN1 and the second bank layer BN2 may include stepped portions corresponding to the bank contact hole CNHB in a portion overlapping the bank contact hole CNHB.

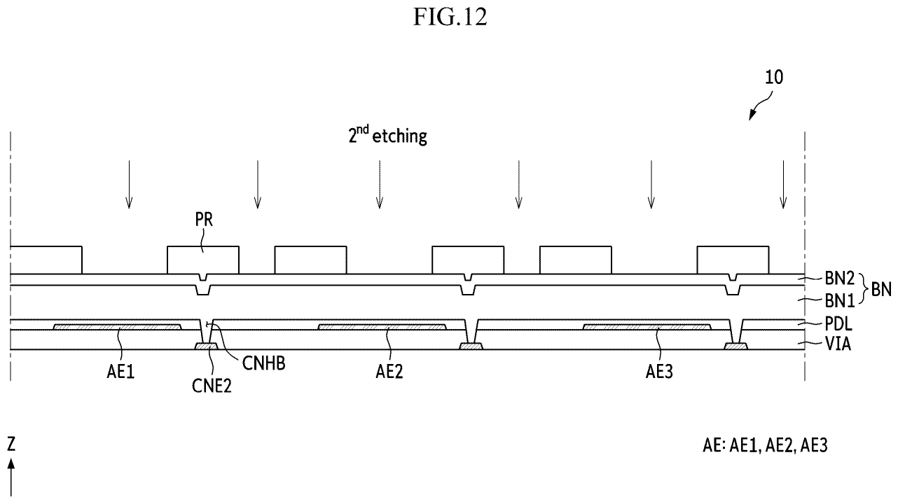

Subsequently, referring to FIGS. 12 to 14, a plurality of photoresists PR are formed on the second bank layer BN2. The plurality of photoresists PR may be spaced apart from each other. Subsequently, a second etching process (2^{nd} etching) is performed using the plurality of photoresists PR as a mask. For example, the second etching process (2^{nd} etching) may be performed by alternately performing a dry etching process and a wet etching process.

For example, first, a dry etching process is performed to isotropically remove parts of the first bank layer BN1 and the second bank layer BN2, which do not overlap the plurality of photoresists PR.

In this process, a first hole HOL1 and a second hole HOL2 may be formed. The first hole HOL1 may be located in a portion that overlaps the anode electrode AE, and the second hole HOL2 may be located in a portion that does not overlap the anode electrode AE, and located between the plurality of anode electrodes AE. The first hole HOL1 may be formed in a portion overlapping the emission area EA shown in FIG. 5.

In this process, one surfaces of the first bank layer BN1 and the second bank layer BN2 facing the first hole HOL1 and the second hole HOL2 may be located on the same line.

Next, a wet etching process is performed to anisotropically remove parts of the first bank layer BN1 and the second bank layer BN2, which non overlap the plurality of photoresists PR. According to some embodiments, the first bank layer BN1 and the second bank layer BN2 may have different etching selectivities in the same process. In other words, the etching rate of the first bank layer BN1 may be higher than the etching rate of the second bank layer BN2 with respect to the same etchant.

In this process, the second bank layer BN2 may include the first tip TIP1 that protrudes toward the first hole HOL1 beyond the first side surface 1c of the first bank layer BN1, and the second tip TIP2 that protrudes toward the second hole HOL2 beyond the second side surface 1d of the first bank layer BN1.

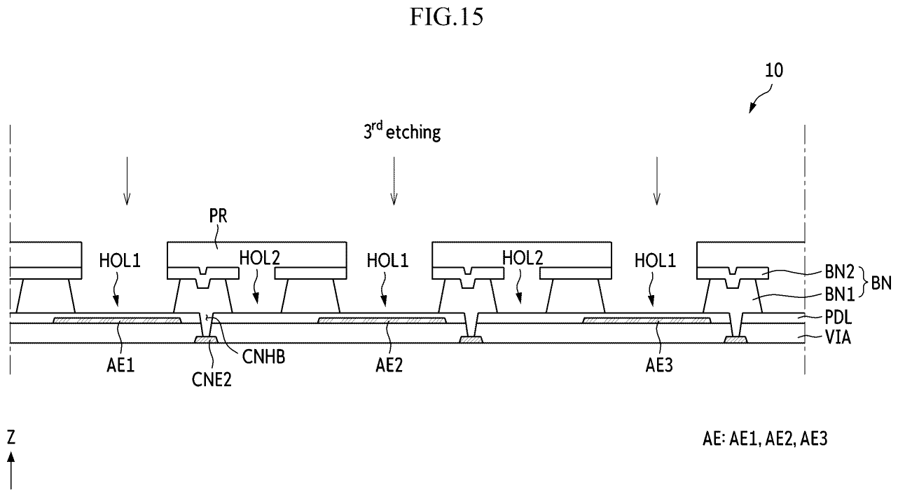

Then, referring to FIGS. 15 to 18, the plurality of photoresists PR are formed on the second bank layer BN2 to entirely cover the second hole HOL2. Subsequently, a third etching process (3^{rd} etching) is performed using the plurality of photoresists PR as a mask. For example, the third etching process (3^{rd} etching) may be performed as a dry etching process.

In this process, a part of the pixel defining layer PDL overlapping the first hole HOL1 may be removed, thereby exposing the anode electrode AE.

Next, the first light emitting layer EL1 and the first cathode electrode CE1 are deposited on the first anode electrode AE1 to form the first light emitting element ED1.

In the present process, the first light emitting layer EL1 may be formed through a thermal evaporation process. For example, the process of forming the first light emitting layer EL1 may be performed without using a separate fine metal mask. For example, the process of forming the first light emitting layer EL1 may be performed by being tilted at an angle of 45° to 50° from the top surface of the first anode electrode AE.

In this process, the material forming the first light emitting layer EL1 may be formed not only on the first anode electrode AE1, but also on the second anode electrode AE2, the third anode electrode AE3, the second bank layer BN2 and the pixel defining layer PDL overlapping the second hole HOL2. In addition, the material forming the first light emitting layer EL1 may also be formed on the first side surface 1c of the first bank layer BN1.

In some embodiments, the material forming the first light emitting layer EL1 may also be formed on the second side surface 1d of the first bank layer BN1, but embodiments according to the present disclosure are not limited thereto.

In the present process, the first cathode electrode CE1 may be formed through a thermal evaporation process or a sputtering deposition process. The process of forming the first cathode electrode CE1 may be performed without a separate fine metal mask and may have a higher step coverage than the deposition process of forming the first light emitting layer EL1. Accordingly, the material forming the first cathode electrode CE1 may entirely cover the material forming the first light emitting layer EL1.

In this process, the material forming the first cathode electrode CE1 may be formed not only on the first anode electrode AE1, but also on the second anode electrode AE2, the third anode electrode AE3, the second bank layer BN2, and the pixel defining layer PDL overlapping the second hole HOL2. In addition, the material forming the first cathode electrode CE1 may also be formed on the first side surface 1c of the first bank layer BN1.

In some embodiments, the material forming the first cathode electrode CE1 may also be formed on the second side surface 1d of the first bank layer BN1, but embodiments according to the present disclosure are not limited thereto.

Subsequently, the element inorganic layer IO is formed on the first light emitting element ED1. The element inorganic layer IO may be entirely formed. For example, the material forming the element inorganic layer IO may be formed not only on the first light emitting element ED1, but also on the second anode electrode AE2, the third anode electrode AE3, the second bank layer BN2 and the pixel defining layer PDL in the portion overlapping the second hole HOL2.

Next, the photoresist PR is formed on the element inorganic layer IO in the first light emitting element ED1 and the portion adjacent to the first light emitting element ED1. Subsequently, a fourth etching process (4^{th} etching) is performed using the photoresist PR as a mask. For example, the fourth etching process (4^{th} etching) may be performed by alternately performing a dry etching process and a wet etching process.

In this process, a material forming the first light emitting layer EL1 that does not overlap the photoresist PR, a material forming the first cathode electrode CE1, and a material forming the element inorganic layer IO may be collectively removed.

In this process, the element inorganic layer IO may be formed in the form of the first element inorganic layer IO1, and the first element inorganic layer IO1 may cover the first light emitting element ED1 and the first tip TIP1 of the second bank layer BN2. The first element inorganic layer IO1 may not overlap the second tip TIP2 of the second bank layer BN2, and thus the second tip TIP2 may be exposed.

In this process, the first element inorganic layer IO1 and the second bank layer BN2 may be spaced apart from each other with a cavity interposed therebetween, in the third direction (Z-axis direction). The cavity may be formed by removing the material forming the first cathode electrode CE1 and the material forming the first light emitting layer EL1 temporarily located on the second bank layer BN2.

In this process, the first holes HOL1 may be formed again in the portions overlapping the second anode electrode AE2 and the third anode electrode AE3, and the second anode electrode AE2 and the third anode electrode AE3 located to overlap the first holes HOL1 may be exposed. In addition, the second hole HOL2 may be formed in the portion overlapping the pixel defining layer PDL between the second anode electrode AE2 and the third anode electrode AE3, and the pixel defining layer PDL located to overlap the second hole HOL2 may be exposed.

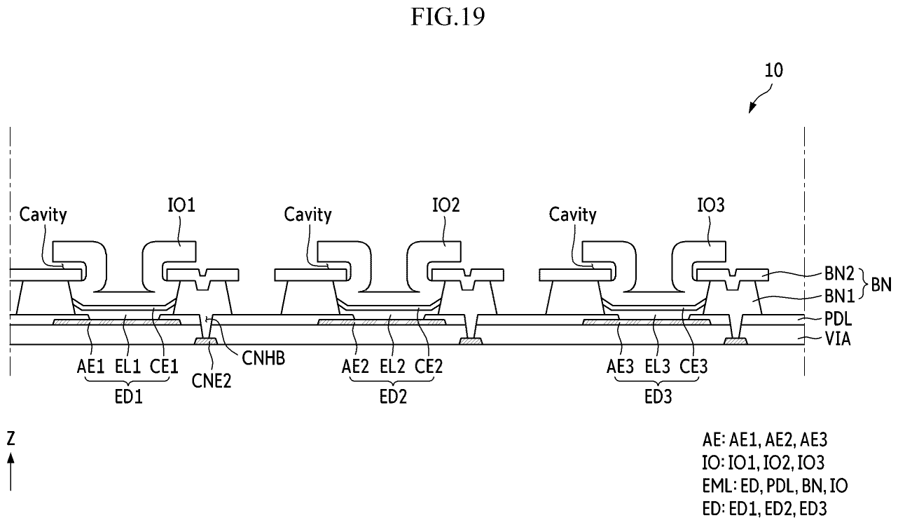

Next, referring to FIG. 19, the same process described above is repeated to form the second light emitting element ED2 and the second element inorganic layer IO2 covering the second light emitting element ED2, and the same process is repeated again to form the third light emitting element ED3 and the third element inorganic layer IO3 covering the third light emitting element ED3.

In these processes, the first element inorganic layer IO1, the second element inorganic layer IO2, and the third element inorganic layer IO3 may be spaced apart from each other. Further, each of the first element inorganic layer IO1, the second element inorganic layer IO2, and the third element inorganic layer IO3 may be spaced apart from the second bank layer BN2 with a cavity interposed therebetween, in the third direction (Z-axis direction). As a result, the display element layer EML illustrated in FIG. 6 may be formed.

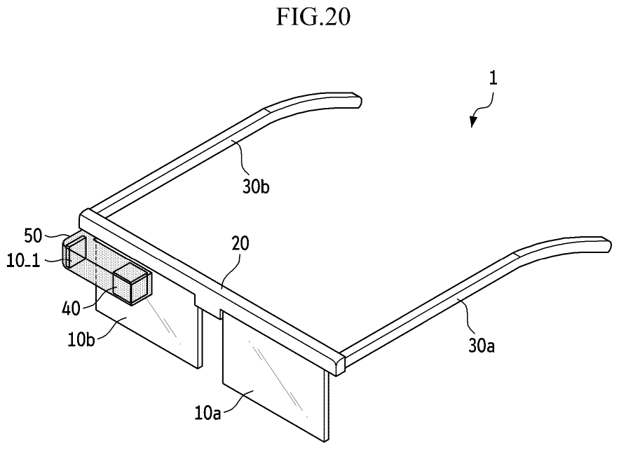

FIG. 20 is a drawing showing an electronic device including a display device according to some embodiments. A display device 10_1 of FIG. 20 may include the display device according to some embodiments of FIGS. 1 to 9 described above.

Referring to FIG. 20, an electronic device 1 may be a glasses-type display. The electronic device 1 may include the display device 10_1, a left eye lens 10a, a right eye lens 10b, a support frame 20, temples 30a and 30b, a reflection member 40, and a display device housing 50.

Optionally, the electronic device 1 may be applied to a head mounted display (HMD) including a head mounted band that may be worn on a head, instead of the temples 30a and 30b. Accordingly, the electronic device 1 is not limited to that shown in FIG. 20 and may be applied to various devices in various forms.

The display device housing 50 may include the display device 10_1 and the reflection member 40. The image displayed on the display device 10_1 may be reflected by the reflection member 40 and provided to a user's right eye through the right eye lens 10b. Thus, the user can view the virtual reality image displayed on the display device 10_1 through the right eye.

The display device housing 50 may be located at the right end of the support frame 20, but the position of the display device housing 50 is not limited thereto. For example, the display device housing 50 may be located at the left end of the support frame 20, and in this case, the image displayed on the display device 10_1 may be reflected by the reflection member 40 and provided to a user's left eye through the left eye lens 10a. Thus, the user can view the virtual reality image displayed on the display device 10_1 through the left eye.

As another example, the display device housing 50 may be located at both the left end and the right end of the support frame 20. In that case, the user can view the virtual reality image displayed on the display device 10_1 through both the left eye and the right eye.

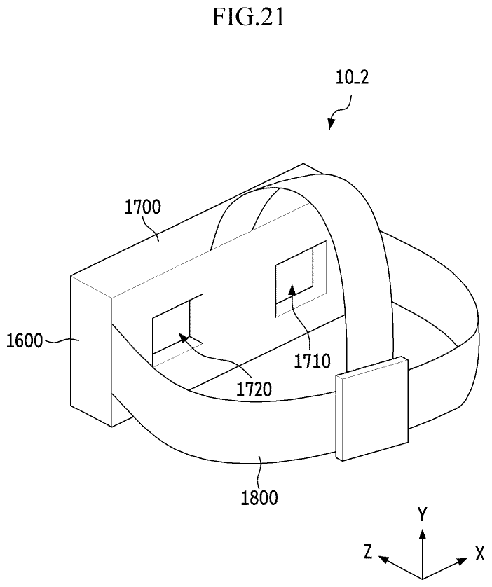

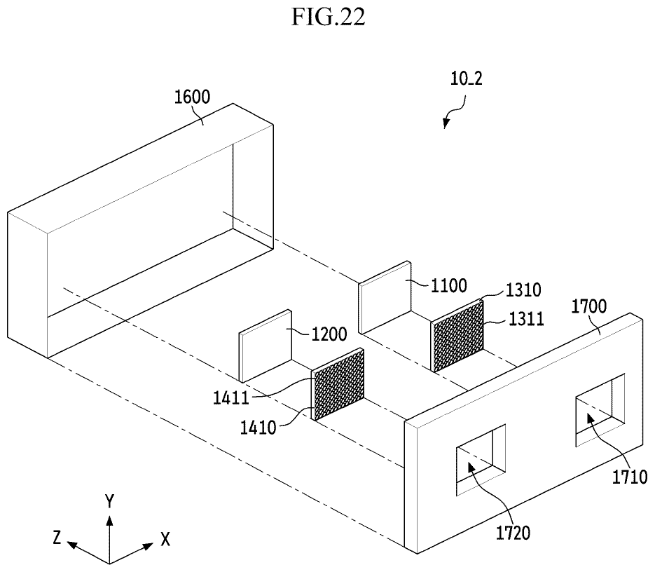

FIGS. 21 and 22 are drawings illustrating a head mounted display including a display device according to some embodiments. A display device 10_2 of FIGS. 21 and 22 may include the display device according to the embodiments of FIGS. 1 to 6 described above.

Referring to FIGS. 21 and 22, the display device 10_2 may be applied to a head mounted display (HMD). A first display device 1100 may provide an image to the user's right eye, and a second display device 1200 may provide an image to the user's left eye.

A first lens array 1310 may be located between the first display device 1100 and a housing cover 1700. The first lens array 1310 may include a plurality of lenses 1311. The plurality of lenses 1311 may include convex lenses that are convex in the direction toward the housing cover 1700.

A second lens array 1410 may be located between the second display device 1200 and the housing cover 1700. The second lens array 1410 may include a plurality of lenses 1411. The plurality of lenses 1411 may include convex lenses that are convex in the direction toward the housing cover 1700.

A display panel housing 1600 may serve to accommodate the first display device 1100, the second display device 1200, the first lens array 1310, and the second lens array 1410. One surface of the display panel housing 1600 may be opened to accommodate the first display device 1100, the second display device 1200, the first lens array 1310, and the second lens array 1410.

The housing cover 1700 may cover the opened surface of the display panel housing 1600. The housing cover 1700 may include a first opening 1710 where the user's right eye is positioned and a second opening 1720 where the user's left eye is positioned. For example, the first opening 1710 and the second opening 1720 may be formed in a quadrilateral shape, but the shapes of the first and second openings 1710 and 1720 are not limited thereto. For another example, the first and second openings 1710 and 1720 may be formed in a circular or oval shape. For still another example, the first and second openings 1710 and 1720 may be integrally formed into a single opening.

The first opening 1710 may be aligned with the first display device 1100 and the first lens array 1310, and the second opening 1720 may be aligned with the second display device 1200 and the second lens array 1410. Accordingly, the user may view an image of the first display device 1100, which is a virtual image enlarged by the first lens array 1310, through the first opening 1710, and an image of the second display device 1200, which is a virtual image enlarged by the second lens array 1410, through the second opening 1720.

A head mounting band 1800 may fix the display panel housing 1600 to the user's head so that the first opening 1710 and the second opening 1720 of the housing cover 1700 are positioned above the user's right and left eyes, respectively. The head mounting band 1800 may be connected to the top, left and right surfaces of the display panel housing 1600.

The display device according to one embodiment of the present disclosure can be applied to various electronic devices. The electronic device according to the one embodiment of the present disclosure includes the display device described above, and may further include modules or devices having additional functions in addition to the display device.

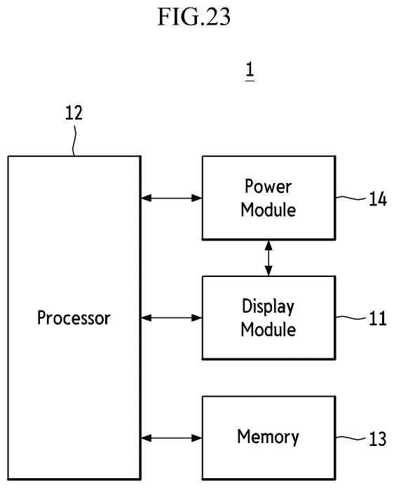

FIG. 23 is a block diagram of an electronic device according to one embodiment of the present disclosure.

Referring to FIG. 23, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

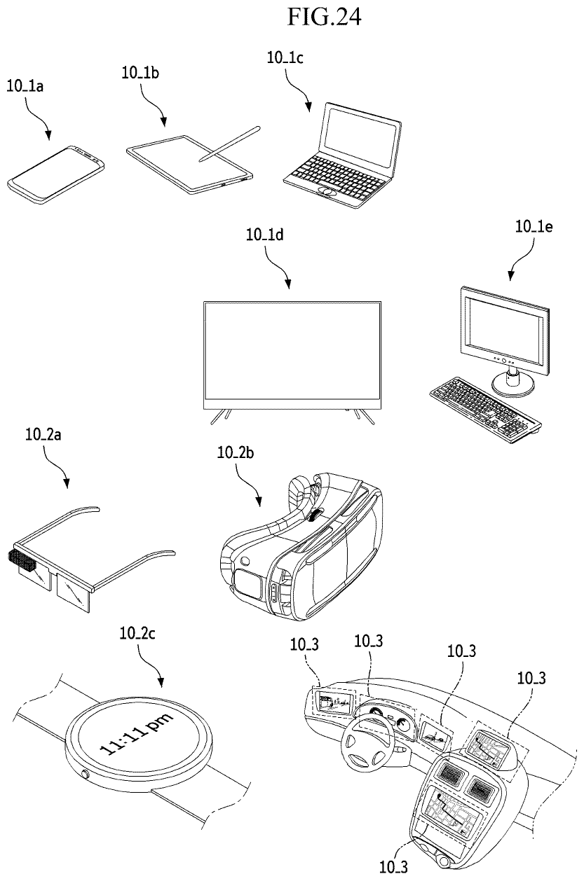

FIG. 24 is a schematic diagram of an electronic device according to various embodiments of the present disclosure.

Referring to FIG. 24, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

Although aspects of some embodiments of the present disclosure have been described with reference to the accompanying drawings, it will be apparent to those skilled in the art that the present disclosure can be embodied in other specific forms without departing from the spirit and scope of embodiments according to the present disclosure. Thus, the above embodiments are to be considered in all respects as illustrative and not restrictive.

Aspects of some embodiments of the present disclosure have been described hereinabove with reference to the accompanying drawings, but it will be understood by one of ordinary skill in the art to which the present disclosure pertains that various modifications and alterations may be made without departing from the technical spirit or essential feature of the present disclosure. Therefore, it should be understood that the embodiments described above are illustrative in all aspects and not restrictive.

Features of various embodiments of the disclosure may be combined partially or totally. As will be clearly appreciated by those skilled in the art, technically various interactions and operations are possible. Also, various embodiments can be practiced individually or in combination.

In concluding the detailed description, those skilled in the art will appreciate that many variations and modifications can be made to the described embodiments without departing from the spirit and scope of embodiments according to the present disclosure. Therefore, the disclosed embodiments of the invention are used in a generic and descriptive sense and not for purposes of limitation.

What is claimed is:

1. A display device comprising:
a pixel circuit comprising a transistor on a substrate comprising an emission area and a non-emission area;
an anode electrode on the emission area of the substrate;
a pixel defining layer on the non-emission area of the substrate and defining a first opening;
a bank structure on the pixel defining layer and defining a second opening, the bank structure comprising a first bank layer and a second bank layer;
a first cathode electrode on the anode electrode, contacting the bank structure, and electrically connected to the transistor; and
a second cathode electrode spaced apart from the first cathode electrode with the pixel defining layer and the bank structure interposed therebetween,
wherein the second cathode electrode contacts the bank structure, and
the bank structure contacting the first cathode electrode and the bank structure contacting the second cathode electrode are spaced apart from each other with a third opening interposed therebetween, in a portion overlapping the non-emission area.

2. The display device of claim 1, wherein the first bank layer comprises a first side surface facing the emission area and a second side surface opposite to the first side surface, and
the second bank layer comprises a first tip protruding toward the first opening beyond the first side surface and a second tip protruding toward the third opening beyond the second side surface.

3. The display device of claim 2, wherein the first cathode electrode contacts the first side surface of the first bank layer.

4. The display device of claim 3, wherein the pixel circuit comprises:
an active region, a drain electrode, and a source electrode of the transistor;
a gate electrode of the transistor on the active region; and
a connection electrode on the gate electrode and connecting the drain electrode to the bank structure.

5. The display device of claim 4, wherein the first cathode electrode is electrically connected to the drain electrode of the transistor through the first bank layer.

6. The display device of claim 2, wherein in a plan view, the first opening is entirely surrounded by the second opening.

7. The display device of claim 6, wherein in the plan view, the first cathode electrode and the second cathode electrode are entirely surrounded by the bank structure, and
in the plan view, the bank structure surrounding the first cathode electrode and the bank structure surrounding the second cathode electrode are spaced apart from each other with the third opening interposed therebetween.

8. The display device of claim 1, wherein the first cathode electrode and the second cathode electrode are electrically insulated from each other.

9. The display device of claim 2, further comprising a light emitting layer located between the anode electrode and the first cathode electrode,
wherein the light emitting layer contacts the first side surface of the first bank layer.

10. The display device of claim 9, wherein the first side surface and the first tip form an undercut and the second side surface and the second tip form an undercut,
in a direction perpendicular to the substrate, the first tip overlaps the light emitting layer and the first cathode electrode, and
the second tip does not overlap the light emitting layer and the first cathode electrode.

11. The display device of claim 1, wherein the pixel defining layer is exposed in a portion overlapping the third opening.

12. The display device of claim 2, wherein the first bank layer contains aluminum, and
the second bank layer contains titanium.

13. The display device of claim 2, further comprising a first element inorganic layer on the first cathode electrode and a second element inorganic layer on the second cathode electrode,
wherein in a portion overlapping the non-emission area, the first element inorganic layer and the second element inorganic layer are spaced apart from each other with the third opening interposed therebetween.

14. The display device of claim 13, wherein the first element inorganic layer is spaced apart from the second bank layer with a cavity interposed therebetween in a direction perpendicular to the substrate.

15. The display device of claim 14, further comprising an organic encapsulation layer on the first element inorganic layer,
wherein the organic encapsulation layer fills the cavity.

16. The display device of claim 13, wherein the first element inorganic layer covers the first tip of the second bank layer, while exposing the second tip.

17. A method for fabrication of a display device, comprising:
forming an anode electrode on a substrate comprising a transistor, and forming a pixel defining layer covering the anode electrode;
forming a bank structure located on the pixel defining layer and comprising a first bank layer and a second bank layer;
removing a part of the bank structure to form a first hole overlapping the anode electrode and a second hole not overlapping the anode electrode; and
forming a light emitting layer, a cathode electrode, and an element inorganic layer on the anode electrode,
wherein the cathode electrode contacts the first bank layer, and
the cathode electrode is electrically connected to the transistor through the first bank layer.

18. The method of claim 17, wherein in the forming of the bank structure, the second bank layer comprises a first tip protruding toward the first hole and a second tip protruding toward the second hole beyond the first bank layer.

19. The method of claim 18, wherein in the forming of the light emitting layer and the cathode electrode, the light emitting layer and the cathode electrode are formed through a deposition and etching process without a separate fine metal mask.

20. An electronic device comprising:
at least one display device comprising a pixel circuit having a transistor on a substrate comprising an emission area and a non-emission area;
a display device housing configured to accommodate the at least one display device; and
an optical member configured to magnify a display image of the at least one display device or change an optical path,
wherein the at least one display device comprises:
an anode electrode on the emission area of the substrate;
a pixel defining layer on the non-emission area of the substrate and defining a first opening;
a bank structure on the pixel defining layer and defining a second opening, the bank structure comprising a first bank layer and a second bank layer;
a first cathode electrode on the anode electrode, in contact with the bank structure, and electrically connected to the transistor; and
a second cathode electrode spaced apart from the first cathode electrode with the pixel defining layer and the bank structure interposed therebetween,
wherein the second cathode electrode contacts the bank structure, and
the bank structure contacting the first cathode electrode and the bank structure contacting the second cathode electrode are spaced apart from each other with a third opening interposed therebetween, in a portion overlapping the non-emission area.
